(19) United States
(12) Patent Application Publication
(10) Pub. No.: US 2023/0110643 A1
(43) Pub. Date: Apr. 13, 2023

(54) METHOD OF MANUFACTURING INTEGRATED CIRCUIT USING ETCHING PROCESS

(71) Applicant: Samsung Electronics Co., Ltd., Suwon-si (KR)

(72) Inventor: Junghwan UM, Seongnam-si (KR)

(73) Assignee: Samsung Electronics Co., Ltd., Suwon-si (KR)

(21) Appl. No.: 17/874,738

(22) Filed: Jul. 27, 2022

(30) Foreign Application Priority Data
Oct. 7, 2021 (KR) 10-2021-0133453

(51) Int. Cl. H01L 21/311; H01L 21/02; H01L 27/108; H01L 27/11556; H01L 27/11582

(52) U.S. Cl. CPC H01L 21/31116; H01L 21/0206; H01L 21/31144; H01L 27/10852; H01L 27/11556; H01L 27/11582

(57) ABSTRACT

A method of manufacturing an integrated circuit (IC) device including forming an etching target structure on a substrate, forming an etching mask pattern having an opening on the etching target structure, etching a portion of the etching target structure through the opening to form a first hole in the etching target structure, forming a conductive polymer layer to cover the etching target structure inside the first hole, and etching another portion of the etching target structure through the first hole, in a state in which the etching target structure is covered by the conductive polymer layer inside the first hole, to form a second hole in the etching target structure and extending from the first hole toward the substrate may be provided.

### CROSS-REFERENCE TO RELATED APPLICATION

This application is based on and claims priority under 35 U.S.C. § 119 to Korean Patent Application No. 10-2021-0133453, filed on Oct. 7, 2021, in the Korean Intellectual Property Office, the disclosure of which is incorporated by reference herein in its entirety.

### BACKGROUND

The inventive concepts relate to integrated circuit (IC) devices, and more particularly, to methods of manufacturing an IC device using a plasma etching process.

Due to the development of the electronic technology, the downscaling of IC devices has rapidly progressed. Thus, structures of the IC devices have become complicated, and aspect ratios of structures included in the IC devices have greatly increased. Accordingly, processes of forming three-dimensional (3D) structures having high aspect ratios also have become stricter. In particular, when a plasma etching process is performed to form patterns having a relatively high aspect ratio during a process of manufacturing an IC device with a high integration, it is necessary to develop a technique of obtaining a desired vertical profile in a pattern obtained after the plasma etching process and a technique of ensuring a desired etch rate.

### SUMMARY

Some example embodiments of the inventive concepts provide methods of manufacturing an integrated circuit (IC) device, wherein when a plasma etching process is performed to form a pattern having a relatively high aspect ratio, a desired vertical profile and a desired etch rate may be ensured, thereby improving reliability and productivity of the IC device.

According to an aspect of the inventive concepts, a method of manufacturing an IC device includes forming an etching target structure on a substrate, forming an etching mask pattern having an opening on the etching target structure, etching a portion of the etching target structure through the opening to form a first hole in the etching target structure, forming a conductive polymer layer to cover the etching target structure inside the first hole, and etching another portion of the etching target structure through the first hole, in a state in which the etching target structure is covered by the conductive polymer layer inside the first hole, to form a second hole in the etching target structure. The second hole extends from the first hole toward the substrate.

According to another aspect of the inventive concepts, a method of manufacturing an IC device includes forming an insulating structure on a substrate, forming an etching mask pattern having an opening on the insulating structure, anisotropically etching the insulating structure through the opening to form a vertical hole, the vertical hole passing through the insulating structure. The anisotropically etching includes etching the portion of the insulating structure through the opening to form a preliminary hole in the insulating structure, forming a conductive polymer layer to cover the insulating structure inside the preliminary hole, and repeating, after the forming a conductive polymer layer, at least once cycle including sequentially performing the etching the portion of the insulating structure and the forming a conductive polymer layer.

According to another aspect of the inventive concepts, a method of manufacturing an IC device includes forming an insulating structure on a substrate, forming an etching mask pattern having an opening on the insulating structure, and anisotropically etching the insulating structure through the opening to form a vertical hole, the vertical hole passing through the insulating structure. The anisotropically etching includes etching a portion of the insulating structure through the opening in a first plasma atmosphere to form a first hole in the insulating structure, forming a conductive polymer layer by supplying a conductive polymer or precursors of the conductive polymer onto the substrate in a second plasma atmosphere, the conductive polymer layer covering sidewalls of the insulating structure inside the first hole, and etching another portion of the insulating structure through the first hole, in a state in which current flows through the conductive polymer layer in a third plasma atmosphere to form a second hole in the insulating structure. The second hole extends from the first hole toward the substrate in a vertical direction.

### BRIEF DESCRIPTION OF THE DRAWINGS

Some example embodiments of the inventive concepts will be more clearly understood from the following detailed description taken in conjunction with the accompanying drawings in which:

FIG. 1 is a flowchart of a method of manufacturing an integrated circuit (IC) device according to an example embodiment;

FIGS. 2A to 2F are cross-sectional views illustrating a process sequence of a method of manufacturing an IC device according to an example embodiment;

FIG. 3 shows pulse supply diagrams of supply gases that are applicable to a method of manufacturing an IC device, according to an example embodiment;

FIGS. 4A to 7B are cross-sectional views illustrating a process sequence of a method of manufacturing an IC device, according to an example embodiment; and

FIGS. 8A to 8J are cross-sectional views illustrating a process sequence of a method of manufacturing an IC device according to an example embodiment.

### DETAILED DESCRIPTION

Hereinafter, some example embodiments will be described in detail with reference to the accompanying drawings. The same reference numerals are used to denote the same elements in the drawings, and repeated descriptions thereof will be omitted.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

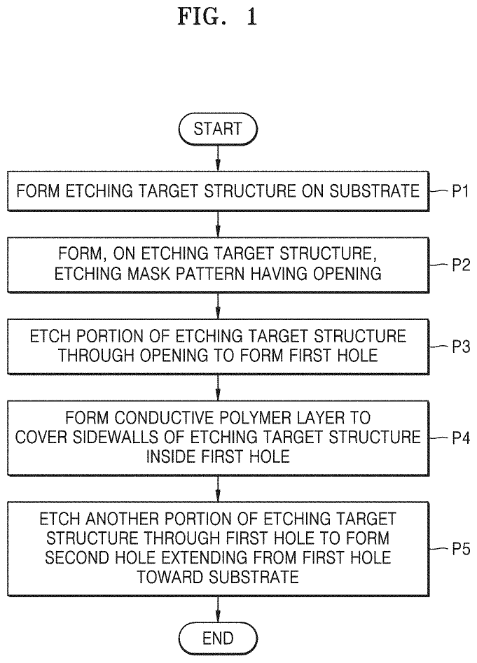

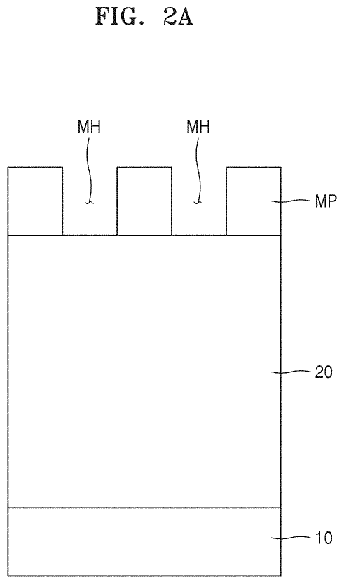

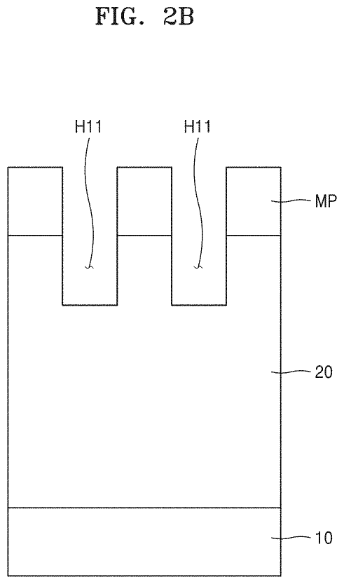

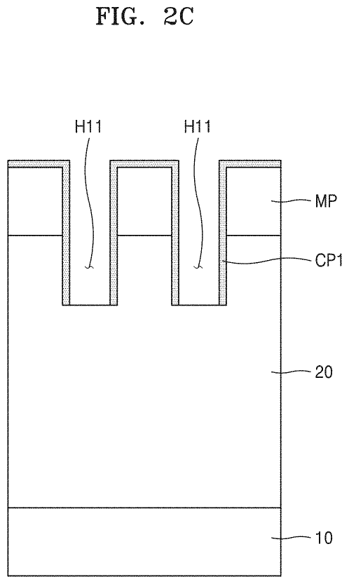

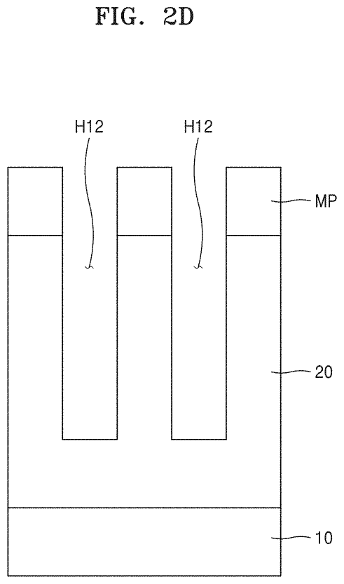

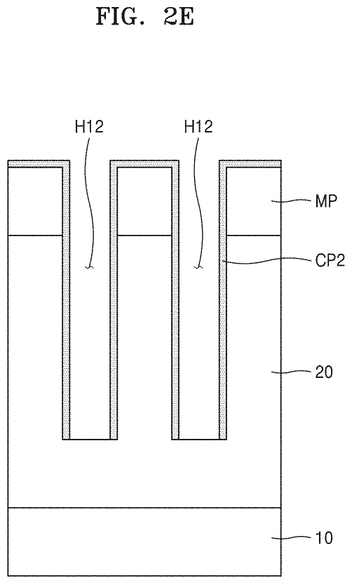

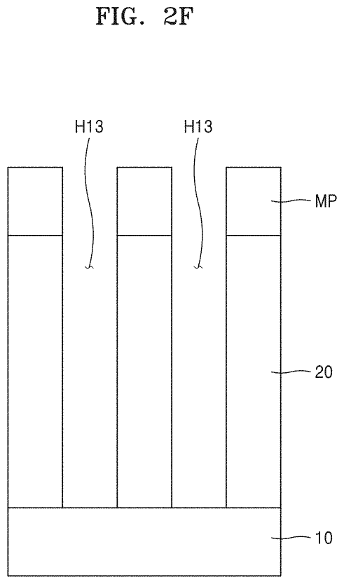

FIG. 1 is a flowchart of a method of manufacturing an integrated circuit (IC) device according to an example embodiment. FIGS. 2A to 2F are cross-sectional views illustrating a process sequence of a method of manufacturing an IC device, according to an example embodiment. The method of manufacturing the IC device, according to the example embodiments, will be described with reference to FIGS. 1 and 2A to 2F.

Referring to FIGS. 1 and 2A, in process P1, an etching target structure 20 may be formed on a substrate 10.

As used herein, the term “substrate” may refer to a substrate itself, or a stack structure including a substrate and a certain layer, film, or the like on a surface of the substrate. In addition, the term “surface of a substrate” may refer to an exposed surface of a substrate itself, or an outer surface of a certain layer, film, or the like on the substrate. The substrate 10 may include a semiconductor substrate. In some example embodiments, the substrate 10 may include an element semiconductor, such as silicon (Si) or germanium (Ge). In other example embodiments, the substrate 10 may include a compound semiconductor, such as silicon germanium (SiGe), silicon carbide (SiC), gallium arsenide (GaAs), indium arsenide (InAs), or indium phosphide (InP). In still other example embodiments, the substrate 10 may have a silicon-on-insulator (SOI) structure. The substrate 10 may include a conductive region, for example, a doped well or a doped structure. In other example embodiments, the substrate 10 may include a transparent substrate.

The etching target structure 20 may include one selected from a semiconductor material, a conductive material, and an insulating material or a combination thereof.

In some example embodiments, the etching target structure 20 may include an insulating structure including at least one insulating film. The at least one insulating film may include a silicon oxide film, a silicon nitride film, a silicon oxynitride film, or a low-k dielectric film having a lower dielectric constant than the silicon oxide film. In some example embodiments, the etching target structure 20 may include tetraethylorthosilicate (TEOS), plasma-enhanced tetraethylorthosilicate (PE-TEOS), O₃-TEOS, undoped silicate glass (USG), phosphosilicate glass (PSG), borosilicate glass (BSG), borophosphosilicate glass (BPSG), fluoride silicate glass (FSG), spin-on-glass (SOG), or a combination thereof.

In other example embodiments, the etching target structure 20 may include a semiconductor film. For example, the etching target structure 20 may include crystalline silicon, amorphous silicon, doped silicon, silicon germanium (SiGe), silicon carbide (SiC), or a combination thereof, without being limited thereto.

In still other example embodiments, the etching target structure 20 may include at least one conductive film. For example, the etching target structure 20 may include a doped polysilicon film, a metal silicide film, a metal film, a metal nitride film, or a combination thereof.

In process P2 of FIG. 1, as shown in FIG. 2A, an etching mask pattern MP having an opening MH may be formed on the etching target structure 20.

In some example embodiments, the etching mask pattern MP may include a spin-on hardmask (SOH), an amorphous carbon layer (ACL), a polysilicon film, an oxide film, a nitride film, a photoresist film, or a combination thereof.

Referring to FIGS. 1 and 2B, in process P3, a portion of the etching target structure 20 may be etched through the opening (refer to MH in FIG. 2A) in the resultant structure of FIG. 2A, and thus, a first hole H11 may be formed in the etching target structure 20. The first hole H11 may extend in a vertical direction from the opening MH toward the substrate 10. The first hole H11 may be a preliminary hole, which is an intermediate product of a vertical hole (e.g., a third hole H13 shown in FIG. 2F) to be finally formed in the etching target structure 20.

The etching process for forming the first hole H11 in the etching target structure 20 according to process P3 of FIG. 1 may be performed by an etching process using plasma. To this end, the resultant structure of FIG. 2A may be loaded into a reaction chamber of a plasma etching apparatus.

In some example embodiments, the plasma etching apparatus may include a reactive ion etching (RIE) equipment, a magnetically enhanced RIE (MERIE) equipment, an inductively coupled plasma (ICP) equipment, a capacitively coupled plasma (CCP) equipment, a hollow-anode-type plasma equipment, a helical resonator plasma equipment, or an electron cyclotron resonance (ECR) plasma equipment

The reaction chamber of the plasma etching apparatus may include a first electrode and a second electrode, which may face each other in the vertical direction and each apply radio frequency (RF) power. The reaction chamber may provide a reaction space in which a plasma etching process is performed between the first electrode and the second electrode. The substrate 10 may be placed in the reaction space on the first electrode such that a main surface of the substrate 10 faces the second electrode. An etching process for forming the first hole H11 may be performed on the etching target structure 20 in a state in which the substrate 10 is placed on the first electrode.

To form the first hole H11 in the etching target structure 20 according to process P3 of FIG. 1, an etching gas mixture may be supplied into the reaction chamber in a plasma atmosphere.

For example, when the etching target structure 20 includes a silicon oxide film, a silicon nitride film, or a combination thereof, the etching gas mixture may include a fluorinated hydrocarbon compound, a reactive gas, and a carrier gas. For example, the fluorinated hydrocarbon compound may include CF₄, C₂F₆, C₄F₆, C₄F₈, CHF₃, CH₂F₂, CH₃F, C₃H₂F₆, C₄H₂F₆, C₄F₆, or a mixture thereof, without being limited thereto. The etching gas mixture may further include a fluorine-containing compound, for example NF₃, HBr, and/or CH₃F. The reactive gas may include O₂, CO, CO₂, NO, NO₂, N₂O, H₂, NH₃, HF, SO₂, CS₂, COS, CF₃I, C₂F₃I, C₂F₅I, or a mixture thereof, without being limited thereto. The carrier gas may include argon (Ar), xenon (Xe), helium (He), neon (Ne), nitrogen (N₂), krypton (Kr), or a mixture thereof, without being limited thereto.

In some example embodiments, the plasma etching process for forming the first hole H11 in the etching target structure 20 may be performed at room temperature (e.g., a temperature of about 20° C. to about 28° C.) to a relatively low process temperature of about 100° C., without being limited thereto.

In some example embodiments, while the plasma etching process for forming the first hole H11 in the etching target structure 20 is being performed according to process P3 of FIG. 1, the first electrode under the substrate 10 in the reaction chamber may not apply RF power, but the RF power may be applied only from the second electrode.

When a portion of the etching target structure 20 is etched using plasma obtained from a fluorinated hydrocarbon compound including a carbon-fluorine (C—F) bond, radicals (e.g. CF, CF₂, F, F₂, and CHF) may be formed, and the etching target structure 20 may be etched in the vertical direction due to the radicals. In this case, charged particles (i.e., electrons and/or ions) supplied from plasma may be accumulated in the etching target structure 20 and the etching mask pattern MP during the etching process. In this case, when the etching process is continuously performed under the same conditions as before, an electric field around an etching target surface of the etching target structure 20 may be disturbed. Accordingly, inside the first hole H11, the radicals may enter a distorted path rather than a desired path in the vertical direction, and thus, a pattern having a profile with a desired shape may not be obtained. In addition, speed at which the radicals enter in the vertical direction inside the first hole H11 may be reduced, and thus, an etch rate of the etching target structure 20 may be non-uniform or reduced.

Referring to FIGS. 1 and 2C, in process P4, a first conductive polymer layer CP1 covering sidewalls of the etching target structure 20 may be formed inside the first hole H11.

As used herein, the term “a conductive polymer” may refer to a polymer that may exhibit conductivity due to intrinsic characteristics thereof without adding an additional conductive material.

The first conductive polymer layer CP1 may conformally cover respective exposed surfaces of the etching target structure 20 and the etching mask pattern MP. The first conductive polymer layer CP1 may include a portion, which extends from an entrance of the first hole H11 toward the substrate 10 in the vertical direction inside the first hole H11. When a subsequent plasma etching process is performed on the resultant structure of FIG. 2C, current may flow through the portion of the first conductive polymer layer CP1, which extends toward the substrate 10 in the vertical direction inside the first hole H11. Accordingly, when the previous plasma etching process described with reference to FIG. 2B is performed, even when charged particles supplied from plasma are accumulated in the etching target structure 20 and the etching mask pattern MP, an undesired potential difference may disappear due to current flowing through the first conductive polymer layer CP1. Because an undesired electric field may be removed in the first hole H11, adverse effects due to charges accumulated in the etching target structure 20 may be mitigated or prevented in a portion adjacent to the bottom of the first hole H11. Accordingly, when a subsequent plasma etching process is performed, radicals that enter the first hole H11 may move in a desired path in the vertical direction. Thus, a pattern having a profile with a desired shape may be obtained, and the non-uniformity or reduction of an etch rate during etching target structure 20 through the first hole H11 may be mitigated or prevented.

The process of forming the first conductive polymer layer CP1 may be performed in a plasma atmosphere. In some example embodiments, the process of forming the first conductive polymer layer CP1 may be performed in the reaction chamber of the plasma etching apparatus, which has been described in process P2 above with reference to FIGS. 1 and 2B.

In some example embodiments, to form the first conductive polymer layer CP1, precursors of a conductive polymer may be supplied onto the substrate 10 in the plasma atmosphere and plasma-polymerized to form the first conductive polymer layer CP1. As used herein, the term “precursor of a conductive polymer” refers to a compound that forms a conductive polymer due to polymerization.

In some example embodiments, the precursors of the conductive polymer may include a compound including a C5-C30 substituted or unsubstituted aromatic ring. For example, the precursors of the conductive polymer may be selected from thiophene, 3-alkyl thiophene, aniline, phenylvinyl sulfone, ortho-xylylene, meta-xylylene, para-xylylene, pyrrole, phenylene vinylene, phenylene, and derivatives thereof, without being limited thereto. The 3-alkyl thiophene may include 3-hexylthiophene or 3-octylthiophene, without being limited thereto.

In some example embodiments, while the process of forming the first conductive polymer layer CP1 is being performed in the reaction chamber of the plasma etching apparatus, which has been described in process P2 above with reference to FIGS. 1 and 2B, the first electrode under the substrate 10 may not apply RF power, but the RF power may be applied only from the second electrode. For example, RF power applied from the first electrode may be about 0 W, RF power applied from the second electrode may be in a range of about 100 W to about 2000 W, and the inside of the reaction chamber may be maintained under a pressure of about 50 mT to about 100 mT, without being limited thereto.

In other example embodiments, to form the first conductive polymer layer CP1, a conductive polymer including a C5-C30 substituted or unsubstituted aromatic ring may be supplied from the outside of the reaction chamber onto the substrate 10. In this case, a molecular weight Mw of the conductive polymer supplied from the outside of the reaction chamber onto the substrate 10 may be in a range of about 2,000 to about 200,000, for example, a range of about 10,000 to about 100,000, without being limited thereto. Thus, the first conductive polymer layer CP1 including the conductive polymer including the C5-C30 substituted or unsubstituted aromatic ring may be obtained.

In some example embodiments, the conductive polymer supplied onto the substrate 10 to form the first conductive polymer layer CP1 may be selected from polythiophene, poly(3-alkyl thiophene), poly(3,4-dialkylthiophene), poly(3,4-cycloalkylthiophene), poly(3,4-dialkoxythiophene), polyaniline, poly(phenyl vinyl sulfoxide), polypyrrole, polyparaphenylene, polyparaphenylenevinylene, poly-p-phenylene sulfide, polyfuran, polyselenophene, polytelurophene, poly(3,4-ethylenedioxythiophene), hydroxy methylated poly(3,4-ethylenedioxythiophene) (PEDOT), poly(3-hexylthiophene) (P3HT), poly(3,4-alkylenedioxy thiophene), N-methyl-2-pyrrolidone (NMP), and derivatives thereof, without being limited thereto. Polyaniline may be in the form of emeraldine salt (EB) having conductivity.

Referring to FIGS. 1 and 2D, in process P5, by using a method similar to process P3 described with reference to FIGS. 1 and 2B, another portion of the etching target structure 20 may be etched through the opening (refer to MH in FIG. 2A) and the first hole H11 in the resultant structure of FIG. 2C, and thus, a second hole H12 may be formed in the etching target structure 20. The second hole H12 may further extend in the vertical direction from the first hole H11 shown in FIG. 2C toward the substrate 10. The second hole H12 may be a preliminary hole, which is an intermediate product of a vertical hole (e.g., the third hole H13 shown in FIG. 2F) to be finally formed in the etching target structure 20.

During the etching of the other portion of the etching target structure 20 to form the second hole H12, the first conductive polymer layer CP1 covering a top surface of the etching mask pattern MP in the resultant structure of FIG. 2C may inhibit the consumption of the etching mask pattern MP and/or increase an etch selectivity of the etching target structure 20 with respect to the etching mask pattern MP. After the second hole H12 is formed, at least a portion of the first conductive polymer layer CP1 in the resultant structure of FIG. 2C may be removed due to an etching atmosphere.

Referring to FIG. 2E, a second conductive polymer layer CP2 may be formed on the resultant structure of FIG. 2D using a method similar to the process of forming the first conductive polymer layer CP1, which has been described in process P4 above with reference to FIGS. 1 and 2C. The second conductive polymer layer CP2 may include a conductive polymer including a C5-C30 substituted or unsubstituted aromatic ring.

Referring to FIG. 2F, by using a method similar to the process of forming the second hole H12 in process P5 described with reference to FIGS. 1 and 2D, still another portion of the etching target structure 20 may be etched through the opening (refer to MH in FIG. 2A) and the second hole (refer to H12 in FIG. 2E) in the resultant structure of FIG. 2E, and thus, the third hole H13 may be formed in the etching target structure 20. The third hole H13 may include a vertical hole, which further extends in the vertical direction from the second hole H12 shown in FIG. 2E toward the substrate 10.

During the etching of the still other portion of the etching target structure 20 to form the third hole H13, the second conductive polymer layer CP2 covering the top surface of the etching mask pattern MP in the resultant structure of FIG. 2E may inhibit the consumption of the etching mask pattern MP and/or increase the etch selectivity of the etching target structure 20 with respect to the etching mask pattern MP. After the third hole H13 is formed, at least a portion of the second conductive polymer layer CP2 in the resultant structure of FIG. 2E may be removed due to an etching atmosphere.

In some example embodiments, processes P3, P4, and P5 of FIG. 1 may be performed in-situ in the reaction chamber of the plasma etching apparatus. In other words, the process of forming the first hole H11 in the etching target structure 20 by etching the portion of the etching target structure 20 according to process P3 of FIG. 1, the process of forming the first conductive polymer layer CP1 according to process P4 of FIG. 1, and the process of forming the second hole H12 in the etching target structure 20 by etching the other portion of the etching target structure 20 according to process P5 of FIG. 1 may be performed in-situ in the reaction chamber of the plasma etching apparatus.

In some example embodiments, after the third hole H13, which is the vertical hole to be finally formed in the etching target structure 20, is formed as in the resultant structure shown in FIG. 2F, a cleaning process for removing the etching mask pattern MP remaining on the resultant structure, residue of the conductive polymer layer, or decomposition products of the conductive polymer layer may be further performed. The cleaning process may be performed in a dry manner, a wet manner, or a combination thereof. When the cleaning process is performed in a wet manner, the etching mask pattern MP may be removed from the resultant structure of FIG. 2F, in which the third hole H13 is formed, and then a hydrogen fluoride (HF)-solution dipping process, a chemical oxide removal (COR) process, or combinations thereof may be performed ex-situ. When the cleaning process is performed in a dry manner, an ashing process using 02 plasma may be performed on the resultant structure of FIG. 2F, in which the third hole H13 is formed. Thereafter, the obtained product may be cleaned using a strip process. The strip process may be performed using alcohol, acetone, or a mixture of nitric acid and sulfuric acid, without being limited thereto.

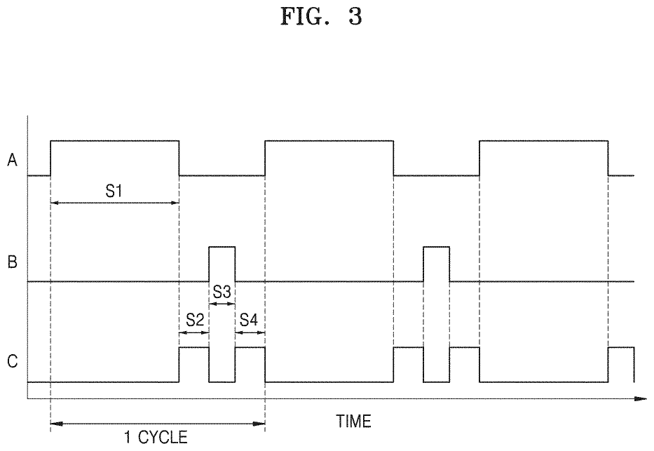

FIG. 3 shows supply pulse diagrams of supply gases that are applicable to a method of manufacturing an IC device, according to an example embodiment. In FIG. 3, “A” denotes an etching gas mixture, “B” denotes precursors of a conductive polymer or a conductive polymer, and “C” denotes a purge gas.

Referring to FIG. 3, in the method of manufacturing the IC device according to the example embodiment, a first sub-process S1 of forming a first hole H11 in an etching target structure 20 by supplying the etching gas mixture into a reaction chamber to etch a portion of the etching target structure 20 according to process P3 of FIG. 1, a second sub-process S2 of exhausting undesirable materials on the substrate 10 out of the reaction chamber by supplying a purge gas onto the substrate 10, a third sub-process S3 of forming a conductive polymer layer (e.g., a first conductive polymer layer CP1) on a surface of the etching target structure 20 in the resultant structure that has been purged according to the second sub-process S2, and a fourth sub-process S4 of exhausting undesirable materials on the substrate 10 out of the reaction chamber by supplying a purge gas onto the resultant structure on which the third sub-process S3 has been performed may be included in one cycle. The cycle may be repeated at least once in-situ, and thus, a vertical hole (e.g., the third hole H13 shown in FIG. 2F) passing through the etching target structure 20 may be formed. As the purge gas, for example, an inert gas (e.g., Ar, He, Ne, or N₂) gas may be used. In some example embodiments, during the one cycle, the first sub-process S1 may be performed for about 30 seconds to about 120 seconds, and the third sub-process S3 may be performed for about 2 seconds to about 10 seconds, without being limited thereto.

In some example embodiments, the processes described with reference to FIGS. 2B and 2C may be omitted from the method of manufacturing the IC device, which has been described with reference to FIGS. 2A to 2F. That is, after the process described with reference to FIG. 2A is performed, the processes described with reference to FIGS. 2B and 2C may be omitted, and a hole (e.g., the second hole H12 shown in FIG. 2D) having a vertical length that corresponds to at least 50% (e.g., about 60% to about 90%) of a total thickness to be etched in the etching target structure 20 in a vertical direction may be formed. Thereafter, the second conductive polymer layer CP2 shown in FIG. 2E may be formed as a firstly introduced conductive polymer layer. Afterwards, the process described with reference to FIG. 2F may be performed to form a vertical hole (e.g., the third hole H13) to be finally formed. In this case, when desired, after the process described with reference to FIG. 2E is performed and before the process described with reference to FIG. 2F is performed, the one cycle described with reference to FIG. 3 may be further performed at least once.

As shown in FIG. 2F, a subsequent process may be performed on the resultant structure in which the third hole H13 is formed in the etching target structure 20, and thus, a vertical plug may be formed to fill the third hole H13. In some example embodiments, the vertical plug may constitute a channel structure, a dummy channel structure, a word line cut structure, a through electrode, and/or a memory cell contact, which constitute a memory cell array structure of a vertical NAND flash memory (hereinafter, vertical NAND (VNAND)). In other example embodiments, the vertical plug may be a lower electrode that constitutes a capacitor of dynamic random access memory (DRAM).

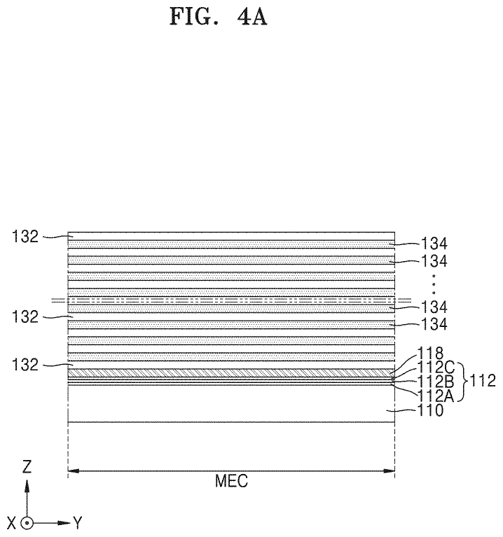

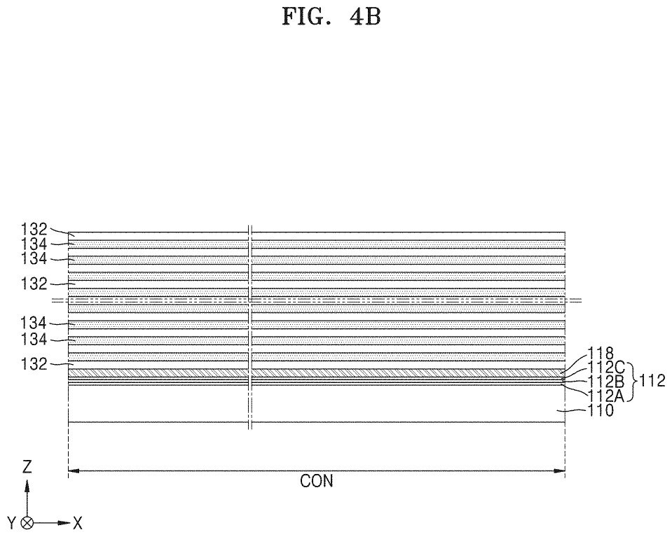

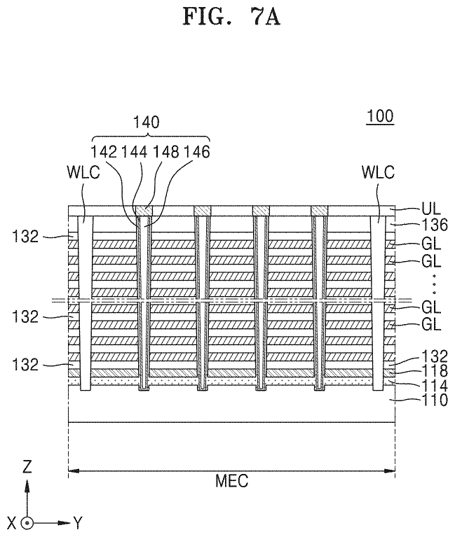

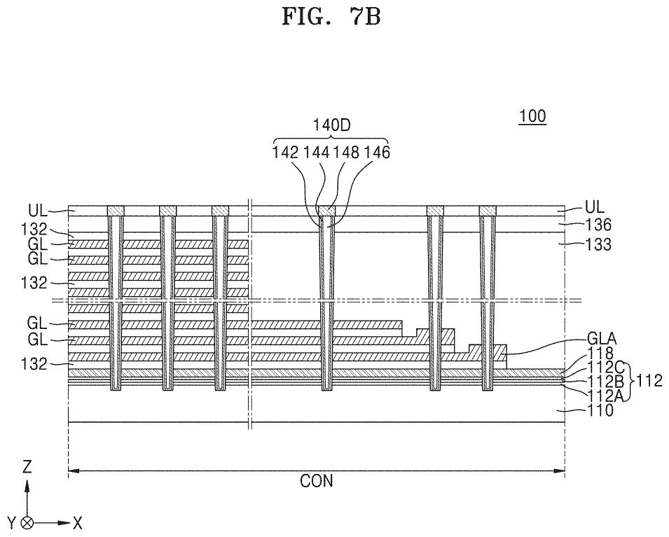

FIGS. 4A to 7B are cross-sectional views illustrating a process sequence of a method of manufacturing an IC device (refer to 100 in FIGS. 7A and 7B) according to an example embodiment. An example method of manufacturing the IC device 100 including a VNAND memory cell array structure will be described with reference to FIGS. 4A to 7B. Of FIGS. 4A to 7B, FIGS. 4A, 5A, 6A, and 7A are cross-sectional views according to a process sequence in a memory cell region MEC, and FIGS. 4B, 5B, 6B, and 7B are cross-sectional views according to a process sequence in a connection region CON.

Referring to FIGS. 4A and 4B, a substrate 110 including the memory cell region MEC and the connection region CON may be prepared.

The memory cell region MEC may be a region in which a memory cell array of an IC device is arranged, while the connection region CON may be a region in which structures configured to electrically connect the memory cell array in the memory cell region MEC to peripheral circuits. Connection regions CON may be on both sides of the memory cell region MEC in a first lateral direction (X direction), respectively. The substrate 110 may include a semiconductor material, such as polysilicon.

Referring to FIGS. 4A and 4B, an insulating plate 112 and an upper conductive plate 118 may be sequentially formed on the substrate 110 in the memory cell region MEC and the connection region CON. The insulating plate 112 may include a multilayered insulating film including a first insulating film 112A, a second insulating film 112B, and a third insulating film 112C. In some example embodiments, the first insulating film 112A and the third insulating film 112C may include a silicon oxide film, and the second insulating film 112B may include a silicon nitride film. The upper conductive plate 118 may include a doped polysilicon film, a metal film, or a combination thereof. The metal film may include tungsten (W), without being limited thereto.

A plurality of insulating layers 132 and a plurality of sacrificial insulating films 134 may be alternately stacked one by one on the upper conductive plate 118. The plurality of insulating films 132 may include silicon oxide film, and the plurality of sacrificial insulating films 134 may include silicon nitride. The plurality of sacrificial insulating films 134 may ensure spaces for forming a plurality of gate lines (refer to GL in FIGS. 7A and 7B), respectively, in a subsequent process.

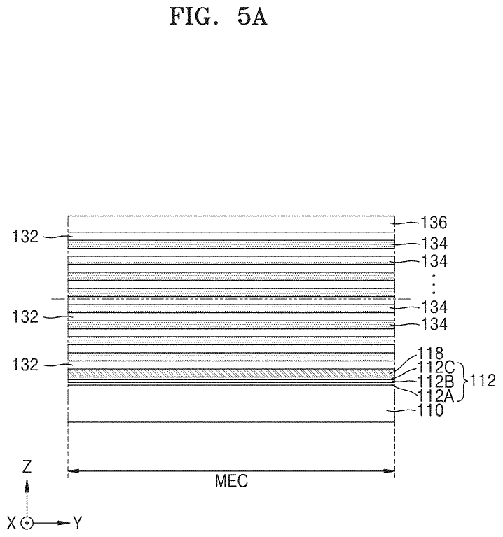

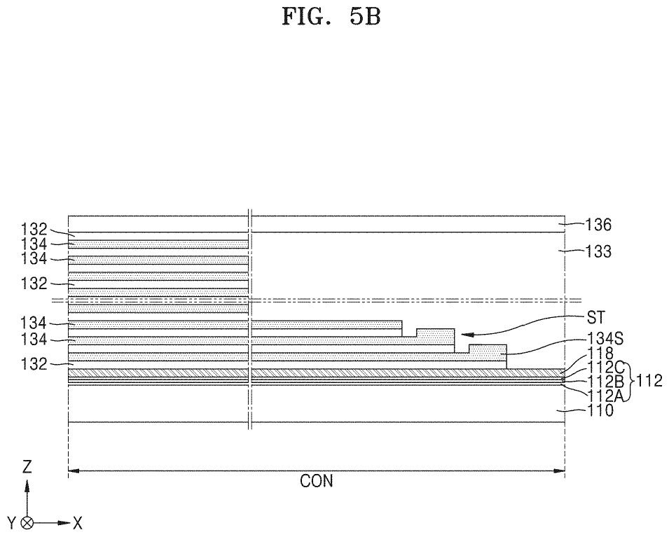

Referring to FIGS. 5A and 5B, a portion of each of the plurality of insulating films 132 and the plurality of sacrificial insulating films 134 may be removed using a photolithography process from the connection region CON of the resultant structure of FIGS. 4A and 4B. Thus, a staircase structure ST in which one end of each of the plurality of insulating films 132 and the plurality of sacrificial insulating films 134 has a gradually smaller lateral width in a direction away from the substrate 110 may be formed. Afterwards, a sacrificial pad unit 134S having an increased thickness may be formed at the one end of each of the plurality of sacrificial insulating films 134 included in the staircase structure ST.

In some example embodiments, the formation of the sacrificial pad unit 134S at the one end of each of the plurality of sacrificial insulating films 134 may include removing portions of the plurality of insulating films 132 to expose the one end of each of the plurality of sacrificial insulating films 134 included in the staircase structure ST, depositing an additional film on the exposed one end of each of the plurality of sacrificial insulating films 134, and patterning the additional film to leave the sacrificial pad unit 134S. The additional film may include the same material as a constituent material of the plurality of sacrificial insulating films 134.

Thereafter, an insulating block 133 may be formed to cover the staircase structure ST and the upper conductive plate 118 in the connection region CON. As a result, the obtained resultant structure may be planarized using a chemical mechanical polishing (CMP) process to remove undesired films, and thus, a top surface of the insulating film 132 that is at a highest level may be exposed.

Afterwards, in the memory cell region MEC and the connection region CON, a middle insulating film 136 may be formed to cover a top surface of each of the insulating film 132 and the insulating block 133 that is at the highest level. Each of the insulating block 133 and the middle insulating film 136 may include a silicon oxide film.

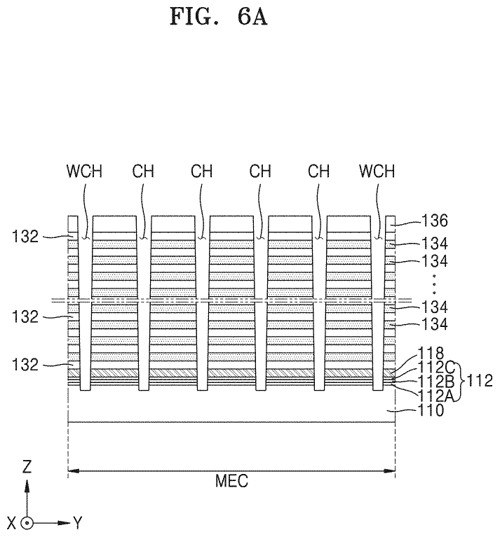

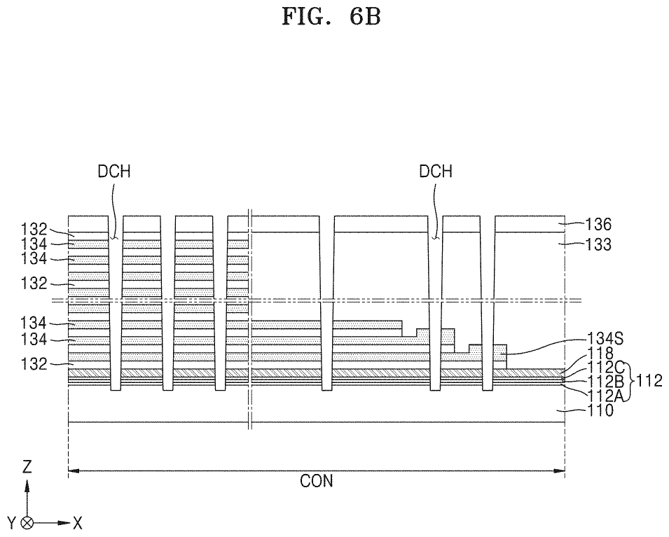

Referring to FIGS. 6A and 6B, an insulating structure including a stack structure of the middle insulating film 136, the insulating block 133, the plurality of insulating films 132, and the plurality of sacrificial insulating films 134, the upper conductive plate 118, and the insulating plate 112 may be dry etched in the connection region CON and the memory cell region MEC, thereby forming a plurality of vertical holes. The plurality of vertical holes may include a plurality of channel holes CH and a plurality of word line cut holes WCH, which are in the memory cell region MEC, and a plurality of dummy channel holes DCH, which are in the connection region CON.

To form the plurality of vertical holes including the plurality of channel holes CH, the plurality of word line cut holes WCH, and the plurality of dummy channel holes DCH, the same or substantially similar methods as the processes of forming the third hole H13, which have been described with reference to FIGS. 1, 2A to 2F, and 3 may be used. By forming the plurality of vertical holes including the plurality of channel holes CH, the plurality of word line cut holes WCH, and the plurality of dummy channel holes DCH as described, during the plasma etching of an etching target structure (e.g., each of the insulating block 133 and the stack structure of the plurality of insulating films 132 and the plurality of sacrificial insulating films 134), even when charged particles supplied from plasma are accumulated in the etching target structure, an undesired potential difference may disappear due to current flowing through a conductive polymer layer (e.g., the first conductive polymer layer CP1 shown in FIG. 2C and/or the second conductive polymer layer CP2 shown in FIG. 2E). Accordingly, an undesired electric field may be removed during an intermediate process of forming the plurality of vertical holes, and thus, adverse effects due to charges accumulated in the etching target structure may be mitigated or prevented. As a result, during the plasma etching process for forming the plurality of vertical holes, radicals may move in a desired path in a vertical direction. Therefore, a plurality of vertical holes having a profile with a desired shape may be obtained, and the non-uniformity or reduction of an etch rate for forming the plurality of vertical holes may be mitigated or prevented.

Referring to FIGS. 7A and 7B, a plurality of channel structures 140 filling the plurality of channel holes CH may be formed in the memory cell region MEC, a plurality of word line cut structures WLC filling the plurality of word line cut holes WCH may be formed in the memory cell region MEC. A plurality of dummy channel structure 140D filling the plurality of dummy channel holes DCH may be formed in the connection region CON. An upper insulating film UL covering the middle insulating film 136 may be formed in the connection region CON and the memory cell region MEC. The upper insulating film UL may include a silicon oxide film.

In some example embodiments, the plurality of channel structures 140 and the plurality of dummy channel structures 140D may be simultaneously formed. Each of the plurality of channel structures 140 and the plurality of dummy channel structure 140D may include a gate dielectric film 142, a channel region 144, a buried insulating film 146, and a drain region 148.

The gate dielectric film 142 may include a tunneling dielectric film, a charge storage film, and a blocking dielectric film, which are sequentially formed on the channel region 144. The tunneling dielectric film may include silicon oxide, hafnium oxide, aluminum oxide, zirconium oxide, and/or tantalum oxide. The charge storage film may include silicon nitride, boron nitride, silicon boron nitride, or doped polysilicon. The blocking dielectric film may include silicon oxide, silicon nitride, or a metal oxide having a higher dielectric constant than silicon oxide. The metal oxide may include hafnium oxide, aluminum oxide, zirconium oxide, tantalum oxide, or a combination thereof.

The channel region 144 may have a cylindrical shape. The channel region 144 may include doped polysilicon or undoped polysilicon.

The buried insulating film 146 may fill an inner space of the channel region 144. The buried insulating film 146 may include an insulating material. For example, the buried insulating film 146 may include silicon oxide, silicon nitride, silicon oxynitride, or a combination thereof. In some example embodiments, the buried insulating film 146 may be omitted. In this case, the channel region 144 in conjunction with the buried insulating film 146 may have a pillar structure having no empty inner space.

The drain region 148 may include doped polysilicon film. A plurality of drain regions 148 included in the plurality of channel structures 140 and the plurality of dummy channel structure 140D may be insulated from each other by the upper insulating film UL.

After the plurality of channel structures 140 and the plurality of dummy channel structure 140D are formed and before the plurality of word line cut structures WLC are formed, the insulating plate 112 may be selectively removed through the plurality of word line cut holes WCH only in the memory cell region MEC, from among the memory cell region MEC and the connection region CON, and the resultant empty space may be filled with a lower conductive plate 114. The lower conductive plate 114 may include a doped polysilicon film, a metal film, or a combination thereof. The metal film may include tungsten (W), without being limited thereto. In the memory cell region MEC, the lower conductive plate 114 and the upper conductive plate 118 may serve as a source region configured to supply current to vertical memory cells included in a cell array structure in the memory cell region MEC.

During the removal of the insulating plate in the memory cell region MEC, in the memory cell region MEC, portions of the gate dielectric film 142, which are included in the channel structure 140 and adjacent to the insulating plate 112, may be removed together with the insulating plate 112. Thus, the lower conductive plate 114 may pass through a partial region of the gate dielectric film 142 in a lateral direction and come into contact with the channel region 144.

In addition, after the lower conductive plate 114 is formed and before the plurality of word line cut structures WLC are formed, in the memory cell region MEC and the connection region CON, the plurality of sacrificial insulating films 134 and the sacrificial pad unit (refer to 134S in FIGS. 5A and 5B) may be replaced by the plurality of gate lines GL and a plurality of conductive pad units GLA through the plurality of word line cut holes WCH. After the lower conductive plate 114, the plurality of gate lines GL, and the plurality of conductive pad units GLA are formed, the plurality of word line cut structures WLC may be formed to fill the plurality of word line cut holes WCH.

Each of the plurality of gate lines GL and the plurality of conductive pad units GLA may include a metal (e.g., tungsten, nickel, cobalt, or tantalum), a metal silicide (e.g., tungsten silicide, nickel silicide, cobalt silicide, or tantalum silicide), doped polysilicon, or a combination thereof. Each of the plurality of word line cut structures WLC may include an insulating structure. In some example embodiments, the insulating structure may include silicon oxide, silicon nitride, silicon oxynitride, or a low-k dielectric material. For example, the insulating structure may include a silicon oxide film, a silicon nitride film, a silicon oxynitride (SiON) film, a silicon oxycarbonitride (SiOCN) film, a silicon carbonitride (SiCN) film, or a combination thereof.

In the IC device 100 manufactured using the method described with reference to FIGS. 4A to 7B, as the stacked number of gate lines GL arranged three-dimensionally in the vertical direction increases, an aspect ratio of the plurality of vertical holes (e.g., the plurality of channel holes CH and the plurality of dummy channel holes DCH shown in FIGS. 6A and 6B) may increase. Thus, it may be desired to form the plurality of vertical holes, each of which has a deep and narrow 3D space. According to some example embodiments, to form the plurality of vertical holes, as in the processes of forming the third hole H13, which have been described with reference to FIGS. 1, 2A to 2F, and 3, the intermediate process of forming the plurality of vertical holes may include forming a conductive polymer layer on sidewalls of the etching target structure. Accordingly, during the plasma etching of the etching target structure, even when charged particles supplied from plasma are accumulated in the etching target structure, an undesired potential difference may disappear due to current flowing through the conductive polymer layer. Thus, during the plasma etching process for forming the plurality of vertical holes including the plurality of channel holes CH and the plurality of dummy channel holes DCH, radicals may move in a desired path in a vertical direction. Thus, a plurality of vertical holes having a profile with a desired shape may be obtained, and the non-uniformity or reduction of an etch rate for forming the plurality of vertical holes may be mitigated or prevented. Therefore, reliability of the IC device 100 may be improved, and/or productivity in the process of manufacturing the IC device 100 may be improved.

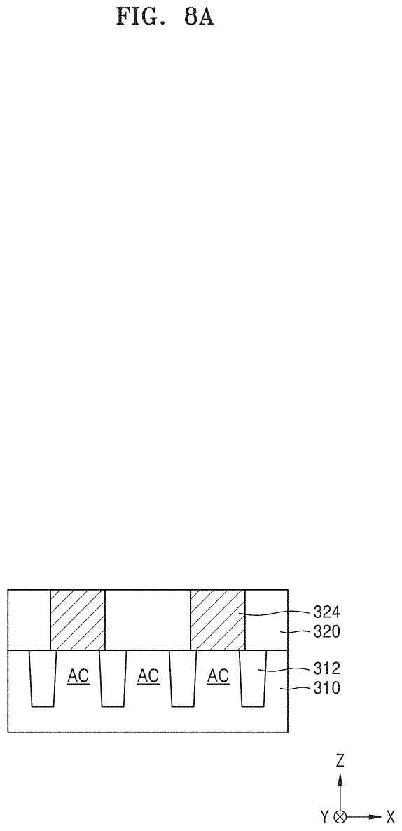

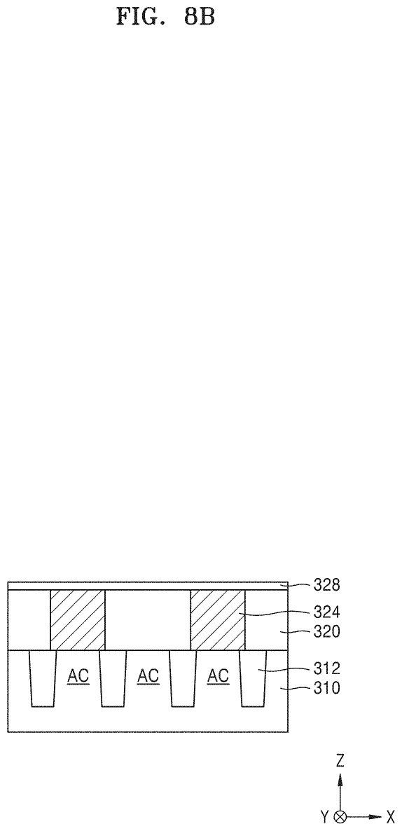

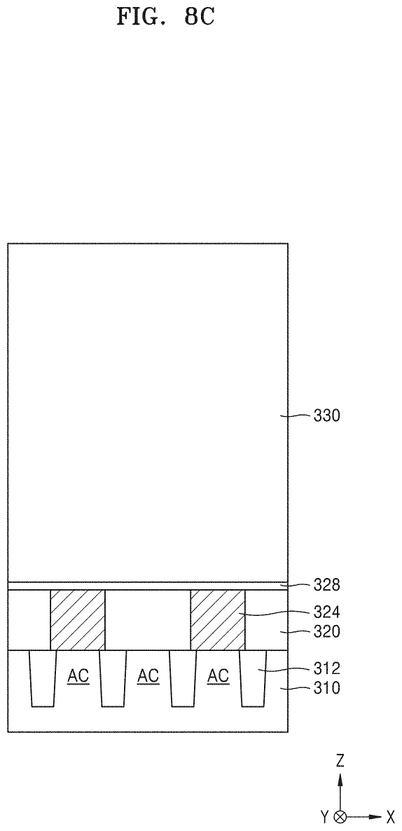

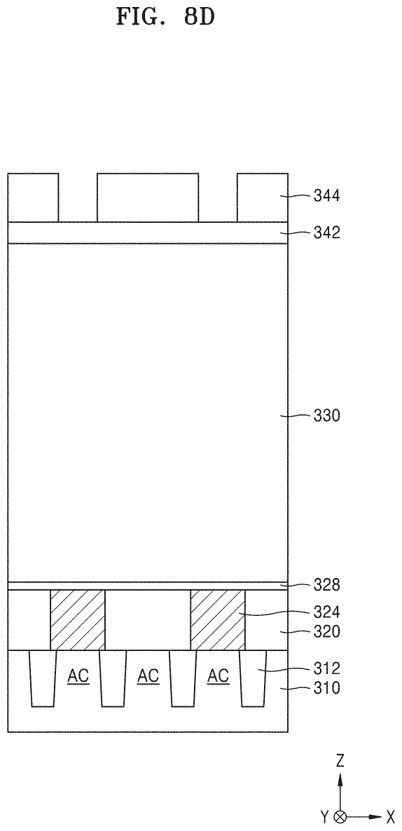

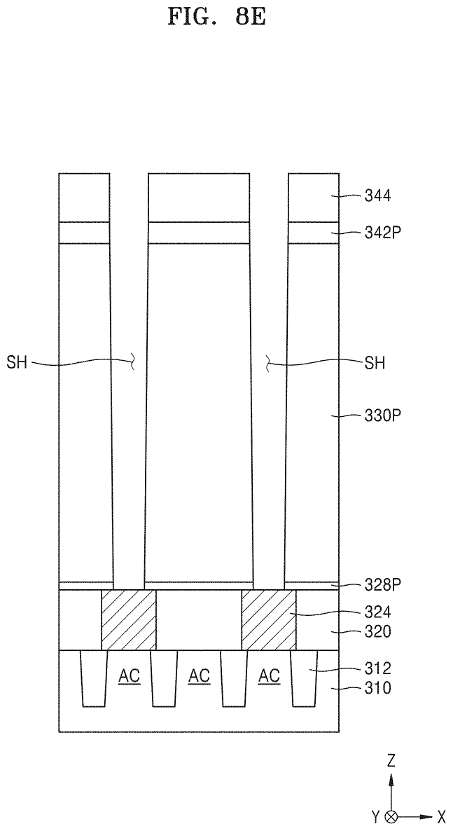

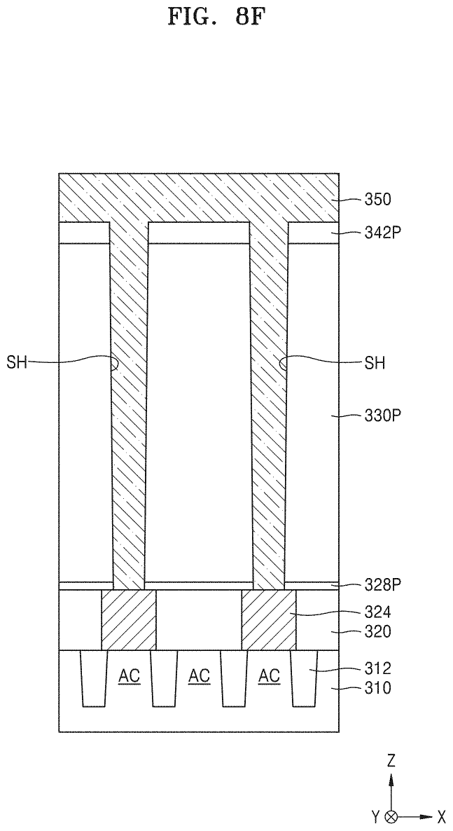

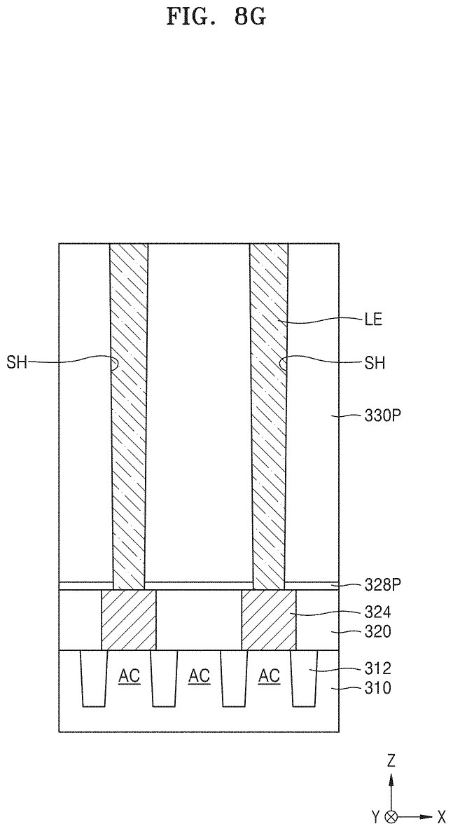

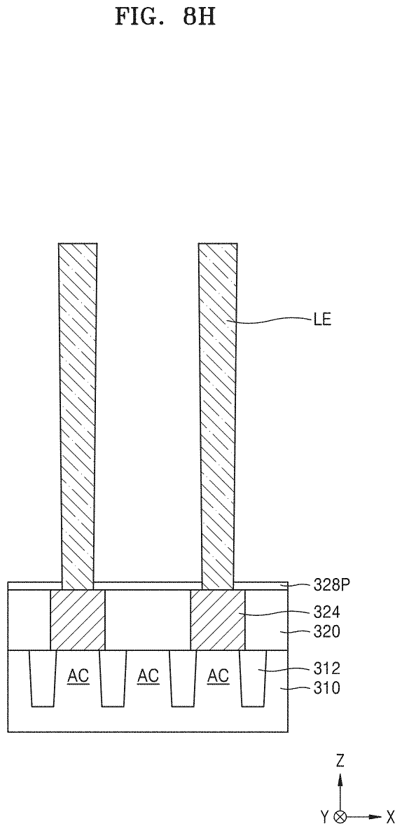

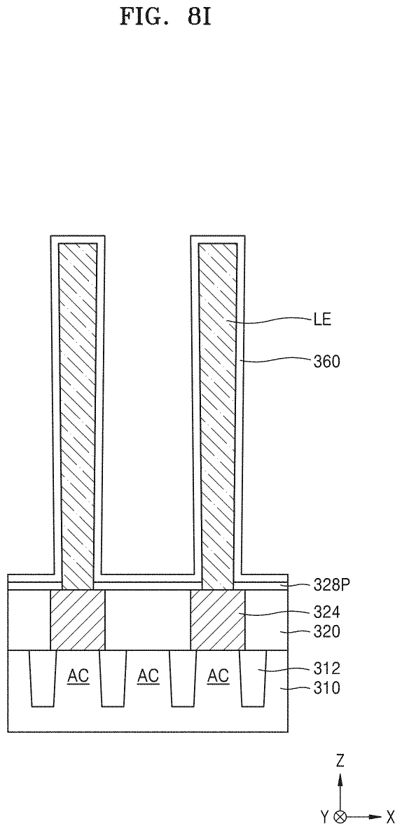

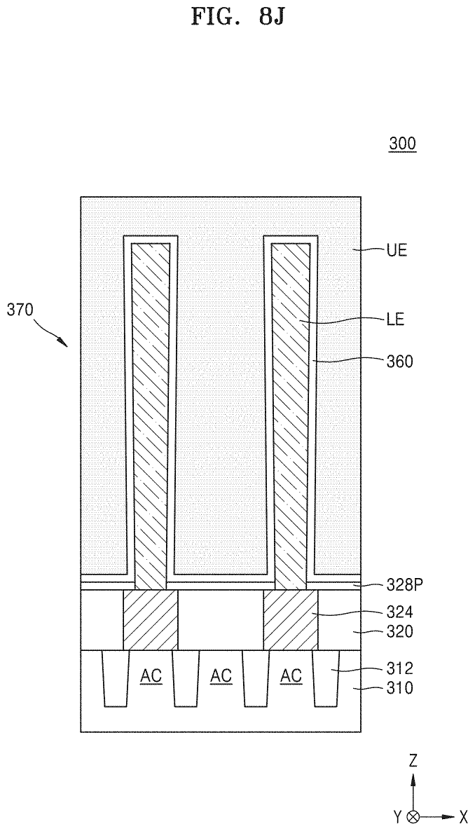

FIGS. 8A to 8J are cross-sectional views illustrating a process sequence of a method of manufacturing an IC device (refer to 300 in FIG. 8J) according to an example embodiment. A method of manufacturing the IC device 300 including a capacitor of DRAM, according to an example embodiment, will be described with reference to FIGS. 8A to 8J.

Referring to FIG. 8A, an interlayer insulating film 320 may be formed on a substrate 310 including a plurality of active regions AC, and then a plurality of conductive regions 324 may be formed to be connected to the plurality of active regions AC through the interlayer insulating film 320.

The substrate 310 may include an element semiconductor (e.g., Si or Ge), or a compound semiconductor (e.g., SiGe, SiC, GaAs, InAs, or InP). The substrate 310 may include a conductive region, for example, a doped well or a doped structure. The plurality of active regions AC may be defined by a plurality of device isolation regions 312 formed in the substrate 310. The device isolation region 312 may include a silicon oxide film, a silicon nitride film, a silicon oxynitride film, or a combination thereof. The interlayer insulating film 320 may include a silicon oxide film. The plurality of conductive regions 324 may be connected to one terminal of a switching element (not shown) (e.g., a field-effect transistor (FET)) formed on the substrate 310. The plurality of conductive regions 324 may include polysilicon, a metal, a conductive metal nitride, a metal silicide, or a combination thereof.

Referring to FIG. 8B, an insulating layer 328 may be formed to cover the interlayer insulating film 320 and the plurality of conductive regions 324. The insulating layer 328 may be used as an etch stop layer. The insulating layer 328 may include an insulating material having an etch selectivity with respect to the interlayer insulating film 320 and a mold film (refer to 330 in FIG. 8C) that will be formed in a subsequent process. The insulating layer 328 may include silicon nitride, silicon oxynitride, or a combination thereof.

Referring to FIG. 8C, the mold film 330 may be formed on the insulating layer 328.

The mold film 330 may include an oxide film. For example, the mold film 330 may include an oxide film (e.g., boro phospho silicate glass (BPSG), phospho silicate glass (PSG), and undoped silicate glass (USG). To form the mold film 330, a thermal chemical vapor deposition (CVD) process or a plasma-enhanced CVD (PECVD) process may be used. The mold film 330 may be formed to a thickness of about 1000 Å to about 20000 Å, without being limited thereto. In some example embodiments, the mold film 330 may include a support film (not shown). The support film may include a material having an etch selectivity with respect to the mold film 330. The support film may include a material having a relatively low etch rate with respect to the mold film 330 in an etching atmosphere (e.g., an etchant including ammonium fluoride (NH₄F), hydrofluoric acid (HF), and water) that is used to remove the mold film 330 in a subsequent process. In some example embodiments, the support film may include silicon nitride, silicon carbonitride, tantalum oxide, titanium oxide, or a combination thereof.

Referring to FIG. 8D, a sacrificial film 342 and a mask pattern 344 may be sequentially formed on the mold film 330. The sacrificial film 342 may include an oxide film. The mask pattern 344 may include an oxide film, a nitride film, a polysilicon film, a photoresist film, or a combination thereof. A region in which a lower electrode of the capacitor will be formed may be defined by the mask pattern 344. The mold film 330 and the sacrificial film 342 may constitute an insulating structure.

Referring to FIG. 8E, the insulating structure including the sacrificial film 342 and the mold film 330 may be plasma-etched by using the mask pattern 344 as an etch mask and using the insulating layer 328 as an etch stop layer, and thus, a plurality of vertical holes and a sacrificial pattern 342P and a mold pattern 330P, which define the plurality of vertical holes, may be formed. The plurality of vertical holes may include a plurality of holes SH. During the formation of the plurality of holes SH, the insulating layer 328 may also be etched due to excessive etching, and thus, an insulating pattern 328P exposing the plurality of conductive regions 324 may be formed.

To form the plurality of vertical holes including the plurality of holes SH, the same or substantially similar method as the processes of forming the third hole H13, which have been described with reference to FIGS. 1, 2A to 2F, and 3, may be used. By forming the plurality of vertical holes including the plurality of holes SH as described above, during the plasma etching of an etching target structure (e.g., the sacrificial film 342 and the mold film 330), even when charged particles supplied from plasma are accumulated in the etching target structure, an undesired potential difference may disappear due to current flowing through a conductive polymer layer (e.g., the first conductive polymer layer CP1 shown in FIG. 2C and/or the second conductive polymer layer CP2 shown in FIG. 2E). Accordingly, an undesired electric filed may be mitigated or removed during an intermediate process of forming the plurality of vertical holes including the plurality of holes SH, and thus, adverse effects due to charges accumulated in the etching target structure may be mitigated or prevented. Therefore, during the plasma etching process for forming the plurality of vertical holes including the plurality of holes SH, radicals may move in a desired path in a vertical direction. Thus, a plurality of vertical holes having a profile with a desired shape may be obtained, and the non-uniformity or reduction of an etch rate for forming the plurality of vertical holes may be mitigated or prevented.

Referring to FIG. 8F, after the mask pattern 344 is removed from the resultant structure of FIG. 8E, a lower electrode-forming conductive film 350 may be formed to fill the plurality of holes SH and cover an exposed surface of the sacrificial pattern 342P.

The lower electrode-forming conductive film 350 may include a doped semiconductor, a conductive metal nitride, a metal, a metal silicide, a conductive oxide, or a combination thereof. In some example embodiments, the lower electrode-forming conductive film 350 may include a doped semiconductor, a conductive metal nitride, a metal, a metal silicide, conductive oxide, or a combination thereof. For example, the lower electrode-forming conductive film 350 may include niobium nitride (NbN), titanium nitride (TiN), titanium aluminum nitride (TiAlN), tantalum nitride (TaN), tantalum aluminum nitride (TaAlN), tungsten (W), tungsten nitride (WN), ruthenium (Ru), ruthenium oxide (RuO₂), strontium ruthenium oxide (SrRuO₃), iridium (Ir), iridium oxide (IrO₂), platinum (Pt), platinum oxide (PtO), SrRuO₃ (SRO), (Ba,Sr)RuO₃ (BSRO), CaRuO₃ (CRO), (La,Sr)CoO₃) (LSCo), or a combination thereof, but a constituent material of the lower electrode-forming conductive film 350 according to the inventive concepts is not limited thereto. To form the lower electrode-forming conductive film 350, a CVD process, a metal organic CVD (MOCVD) process, or an atomic layer deposition (ALD) process may be used.

Referring to FIG. 8G, an upper portion of the lower electrode-forming conductive film 350 may be partially removed, and thus, a plurality of lower electrodes LE may be formed from the lower electrode-forming conductive film 350.

To form the plurality of lower electrodes LE, a part of the upper portion of the lower electrode-forming conductive film 350 and the sacrificial pattern (refer to 342P in FIG. 8F) may be removed using an etchback process or a chemical mechanical polishing (CMP) process until a top surface of the mold pattern 330P is exposed.

Referring to FIG. 8H, the mold pattern 330P may be removed from the resultant structure of FIG. 8G, and thus, outer surfaces of the plurality of lower electrodes LE may be exposed. The mold pattern 330P may be removed by means of a lift-off process using an etchant including ammonium fluoride (NH₄F), hydrofluoric acid (HF), and water.

Referring to FIG. 8I, a dielectric film 360 may be formed on the plurality of lower electrodes LE. The dielectric film 360 may be formed to conformally cover exposed surfaces of the plurality of lower electrodes LE.

In some example embodiments, the dielectric film 360 may include hafnium oxide, hafnium oxynitride, hafnium silicon oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or a combination thereof, without being limited thereto. The dielectric film 360 may be formed using an ALD process. The dielectric film 360 may be formed to a thickness of about 50 Å to about 150 Å, without being limited thereto.

Referring to FIG. 8J, an upper electrode UE may be formed on the dielectric film 360. The lower electrode LE, the dielectric film 360, and the upper electrode UE may constitute a capacitor 370.

The upper electrode UE may include a doped semiconductor, a conductive metal nitride, a metal, a metal silicide, conductive oxide, or a combination thereof. For example, the upper electrode UE may include NbN, TiN, TiAlN, TaN, TaAlN, W, WN, Ru, RuO₂, SrRuO₃, IrO₂, Pt, PtO, SRO(SrRuO₃), BSRO((Ba,Sr)RuO₃), CRO(CaRuO₃), LSCo((La,Sr)CoO₃), or a combination thereof, without being limited thereto. To form the upper electrode UE, a CVD process, an MOCVD process, a physical vapor deposition (PVD) process, or an ALD process may be used.

In the method of manufacturing the IC device, which has been described with reference to FIGS. 8A to 8J, an example in which each of the plurality of lower electrodes LE has a pillar shape has been described, but the inventive concepts are not limited thereto. For example, each of the plurality of lower electrodes LE may include a sectional structure having a cup shape or a cylindrical shape with a closed bottom.

In the IC device 300 manufactured using the method described with reference to FIGS. 8A to 8J, the capacitor 370 may include a lower electrode LE having a three-dimensional (3D) electrode structure. To compensate for a reduction in capacitance due to a reduction in design rule, an aspect ratio of the lower electrode LE having the 3D electrode structure has increased. Accordingly, it may be desired to form a plurality of vertical holes including the plurality of holes (refer to SH in FIG. 8E), each of which has a relatively deep and relatively narrow 3D space. According to some example embodiments, to form the plurality of vertical holes, as in the processes of forming the third hole H13, which have been described above with reference to FIGS. 1, 2A to 2F, and 3, the intermediate process of forming the plurality of vertical holes may include forming a conductive polymer layer on both sidewalls of the etching target structure. Accordingly, during the process of plasma-etching the etching target structure, even when charged particles supplied from plasma are accumulated in the etching target structure, an undesired potential difference may disappear due to current flowing through the conductive polymer layer. Thus, during the plasma etching process for forming the plurality of vertical holes including the plurality of holes SH, radicals may move in a desired path in the vertical direction. Thus, a plurality of vertical holes having a profile with a desired shape may be obtained, and the non-uniformity or reduction of an etch rate for forming the plurality of vertical holes may be mitigated or prevented. Therefore, reliability of the IC device 300 may be improved, and/or productivity in the process of manufacturing the IC device 300 may be improved.

While the inventive concepts have been particularly shown and described with reference to some example embodiments thereof, it will be understood that various changes in form and details may be made therein without departing from the spirit and scope of the following claims.

What is claimed is:

1. A method of manufacturing an integrated circuit device, the method comprising:
forming an etching target structure on a substrate;
forming, on the etching target structure, an etching mask pattern having an opening;
first etching a portion of the etching target structure through the opening to form a first hole in the etching target structure;
forming a conductive polymer layer to cover the etching target structure inside the first hole; and
second etching another portion of the etching target structure through the first hole, in a state in which the etching target structure is covered by the conductive polymer layer inside the first hole, to form a second hole in the etching target structure, the second hole extending from the first hole toward the substrate.

2. The method of claim 1, wherein the first etching and the second etching each are performed by an etching process using plasma.

3. The method of claim 1, wherein the forming a conductive polymer layer is performed in a plasma atmosphere.

4. The method of claim 1, wherein the forming a conductive polymer layer comprises:
supplying precursors of a conductive polymer onto the substrate in a plasma atmosphere; and
forming the conductive polymer layer by plasma-polymerizing the precursors.

5. The method of claim 1, wherein
the forming a conductive polymer layer comprises supplying precursors of a conductive polymer onto the substrate in a plasma atmosphere, and
the precursors comprise a compound including a C5-C30 substituted or unsubstituted aromatic ring.

6. The method of claim 1, wherein
the forming a conductive polymer layer comprises supplying precursors of a conductive polymer onto the substrate in a plasma atmosphere,
the precursors include at least one of thiophene, 3-alkyl thiophene, aniline, phenylvinyl sulfone, ortho-xylylene, meta-xylylene, para-xylylene, pyrrole, phenylene vinylene, phenylene, or derivatives thereof.

7. The method of claim 1, wherein the forming a conductive polymer layer comprises supplying a conductive polymer including a C5-C30 substituted or unsubstituted aromatic ring onto the substrate.

8. A method of manufacturing an integrated circuit device, the method comprising:
forming an insulating structure on a substrate;
forming, on the insulating structure, an etching mask pattern having an opening;
anisotropically etching the insulating structure through the opening to form a vertical hole, the vertical hole passing through the insulating structure,
wherein the anisotropically etching comprises,
etching the portion of the insulating structure through the opening to form a preliminary hole in the insulating structure,
forming a conductive polymer layer to cover the insulating structure inside the preliminary hole, and
repeating at least once a cycle comprising sequentially performing the etching the portion of the insulating structure and the forming a conductive polymer layer, after the forming a conductive polymer layer.

9. The method of claim 8, wherein the anisotropically etching further comprises:
supplying a first purge gas onto the substrate after the etching the portion of the insulating structure and before the forming a conductive polymer layer; and
supplying a second purge gas onto the substrate after the forming a conductive polymer layer.

10. The method of claim 8, wherein the insulating structure comprises an oxide film.

11. The method of claim 8, wherein the insulating structure comprises a plurality of silicon oxide films and a plurality of silicon nitride films, which are alternately stacked one by one in a vertical direction.

12. The method of claim 8, wherein the etching the portion of the insulating structure is performed using plasma obtained from an etching gas mixture comprising a fluorinated hydrocarbon compound.

13. The method of claim 8, further comprising:
after the anisotropically etching, forming a channel structure inside the vertical hole.

14. The method of claim 8, further comprising:
after the anisotropically etching,
forming a lower electrode of a capacitor inside the vertical hole, and
exposing a surface of the lower electrode by removing the insulating structure, after the forming a lower electrode.

15. The method of claim 8, further comprising:
after the anisotropically etching, performing a cleaning process to remove residue of the conductive polymer layer from a resultant structure comprising the vertical hole,
wherein the cleaning process is performed by a wet process using a hydrogen fluoride (HF) solution.

16. The method of claim 8, further comprising:
after the anisotropically etching, performing a cleaning process to remove residue of the conductive polymer layer from a resultant structure comprising the vertical hole,
wherein the cleaning process is performed by a dry process using O₂ plasma.

17. The method of claim 8, wherein the forming a conductive polymer layer comprises:
supplying precursors of a conductive polymer onto the substrate in a plasma atmosphere; and
forming the conductive polymer layer by plasma-polymerizing the precursors,
wherein the precursors comprise a compound including a C5-C30 substituted or unsubstituted aromatic ring.

18. The method of claim 8, wherein the forming the conductive polymer layer comprises supplying a conductive polymer including a C5-C30 substituted or unsubstituted aromatic ring onto the substrate.

19. A method of manufacturing an integrated circuit device, the method comprising:
forming an insulating structure on a substrate;
forming, on the insulating structure, an etching mask pattern having an opening; and
anisotropically etching the insulating structure through the opening to form a vertical hole, the vertical hole passing through the insulating structure,
wherein the anisotropically etching comprises,
etching a portion of the insulating structure through the opening in a first plasma atmosphere to form a first hole in the insulating structure,
forming a conductive polymer layer by supplying a conductive polymer or precursors of the conductive polymer onto the substrate in a second plasma atmosphere, the conductive polymer layer covering sidewalls of the insulating structure inside the first hole, and
etching another portion of the insulating structure through the first hole, in a state in which current flows through the conductive polymer layer in a third plasma atmosphere, to form a second hole in the insulating structure, the second hole extending from the first hole toward the substrate in a vertical direction.

20. The method of claim 19, wherein the conductive polymer layer comprises a conductive polymer including a C5-C30 substituted or unsubstituted aromatic ring.
